(19) United States
(12) Patent Application Publication
(10) Pub. No.: US 2004/0203255 A1
(43) Pub. Date: Oct. 14, 2004

(54) Method of forming Si-containing thin film

(75) Inventor: Atsushi Itsuki, Naka-gun (JP)

Correspondence Address: DARBY & DARBY P.C., P. O. BOX 5257, NEW YORK, NY, 10150-5257, US

(73) Assignee: MITSUBISHI MATERIALS CORPORATION, Tokyo (JP)

(21) Appl. No.: 10/777,469

(22) Filed: Feb. 11, 2004

(30) Foreign Application Priority Data
Feb. 13, 2003 (JP) P2003-034560
Jan. 13, 2004 (JP) P2004-005285

(51) Int. Cl. H01L 21/469

(52) U.S. Cl. 438/778

(57) ABSTRACT

The method of forming a Si-containing thin film forms a film using an organic Si-containing compound having a Si—Si bond represented by the following formula (I):

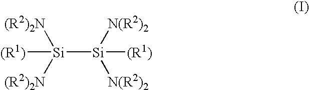

wherein R¹ represents a hydrogen or a methyl group, and R² represents a methyl group, an ethyl group, a propyl group or a tertiary butyl group.

### BACKGROUND OF THE INVENTION

1. Field of the Invention

The present invention relates to a method of forming an Si-containing thin film using an organic Si-containing compound which has a Si—Si bond. The application is based on Japanese patent Application No. 2003-034560 filed on Feb. 13, 2003 and Japanese patent Application no. 2004-005285 filed on Jan. 13, 2004, which are hereby incorporated by reference in their entirety.

2. Description of the Related Art

While a silicon oxide film is used as a gate insulation film for a dielectric having high dielectric constant, increasingly thinner silicon oxide films are being made in line with the recent trend of higher integration of LSIs. A thin silicon oxide film having thickness of 100 nm or less has insufficient insulation effect since tunnel current flows therein, and therefore, the limit of decreasing thickness of the silicon oxide film is aforementioned thickness.

Thus there is a demand for an alternative gate insulation film that would replace the silicon oxide film, and silicon-containing thin films such as Si₃N₄ thin film and Hf—O—Si thin film are noted as promising. While such thin films can be formed by sputtering, ion plating, spin on-thermal decomposition, and MOD (metal organic deposition) of sol-gel or the like, a metal organic chemical vapor deposition method (hereafter referred to as a MOCVD method) is being researched as the most appropriate method of forming thin films in consideration of such factors as the high capability to control the composition, high capability to cover steps and compatibility with the semiconductor manufacturing process.

Hexachlorodisilane (hereafter referred to as Si₂Cl₆) is commonly used to form silicon-containing thin films such as Si₃N₄ thin film and Hf—O—Si thin film. Si₃N₄ film, for example, is formed by heating Si₂Cl₆ and NH₃ so as to react with each other. Not all of Si₃N₄, which is the product of this reaction, deposits on a substrate, and a part of it is deposited on an exhaust tube or other part of the film forming apparatus. If the film forming operation is continued while allowing such a deposit formed on the tube and the like to remain, the deposit will eventually come off, producing particulate matter. When the particulate matter is deposited on a-silicon substrate and the like, production yield may deteriorate. For this reason, maintenance service is periodically conducted to remove the deposit formed on the tube and the like by cleaning the inside of the film forming apparatus with a solution of hydrofluoric acid or the like.

When Si₂Cl₆ and NH₃ are reacted with heating, a compound composed of Si—Cl—N—H is produced as a reaction intermediate, in addition to Si₃N₄. The reaction intermediate is contained in the exhaust gas that passes the exhaust tube and in the deposited material. The reaction intermediate can be easily hydrolyzed, thereby releasing heat of reaction and hydrochloric acid and producing a hydrolysate. As a consequence, there have been problems in that disassembling the exhaust tube and the like for the maintenance service while the reaction intermediate is deposited causes the reaction intermediate to react with moisture in the atmosphere, thereby the reaction intermediate is hydrolyzed and hydrochloric acid gas is generated.

In order to solve the problem described above, a method has been proposed in which a material to be processed is put in a reaction chamber, gas in the reaction chamber is discharged through an exhaust tube connected to the reaction chamber, while Si₂Cl₆ and NH₃ are supplied into the reaction chamber, thereby forming an Si₃N₄ film on the material to be processed, wherein the exhaust tube is heated to a temperature that allows NH₄Cl to evaporate and NH₃ is supplied into the exhaust tube (see, for example, Japanese Unexamined Patent Publication No. 2002-334869). According to the patent document, the reaction intermediate produced during the reaction is reacted with NH₃ by supplying NH₃ into the exhaust tube, thereby to turn into a compound composed of Si—N—H which is less likely to evolve a hydrochloric acid, thereby to suppress the evolution of toxic gas.

When a film is formed by the thermal CVD method using a chlorine-containing Si—Si compound such as Si₂Cl₆ disclosed in the document, a Si—Si bond is first cleaved to form radical species having a Si—Cl bond. However, the Si—Cl bond is less likely to be cleaved under the film forming conditions that involve a high temperature such as 700° C., and Cl incorporated in the film thus formed. Cl is incorporated in the film increases the stress due to the film forming temperature leading to the occurrence of cracks, thus resulting in a decrease in the production yield.

Even when the film is formed at a low temperature less than 700° C. so as to suppress the stress generated due to the film forming temperature and decrease the occurrence of cracks, film formation at a lower temperature allows the Cl content incorporated in the film to increase, which in turn decreases the film strength, thus making it difficult to form a flat film.

Moreover, Si₂Cl₆ is a material which ignite easily in air and therefore handling thereof with care is required. Thus there has been a demand for an alternative compound.

### BRIEF DESCRIPTION OF THE DRAWINGS

FIG. 1 is a schematic view showing a MOCVD apparatus.

FIG. 2 is a schematic view showing a MOCVD apparatus having another structure.

### SUMMARY OF THE INVENTION

An object of the present invention is to provide a method of forming a Si-containing thin film using an organic Si-containing compound having a Si—Si bond, which is excellent in vaporization stability and has a high film forming rate.

Another object of the present invention is to provide a method of forming a Si-containing thin film using an organic Si compound having a Si—Si bond, which enables gas phase deposition at a temperature lower than that of the conventional organic Si compound and produces a film having higher strength.

That is, a method of the present invention is a method of forming a Si-containing thin film, which comprises forming a film using an organic Si-containing compound having a Si—Si bond represented by the following formula (I):

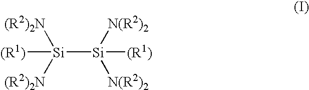

wherein R¹ represents a hydrogen or a methyl group, and R² represents a methyl group, an ethyl group, a propyl group or a tertiary butyl group.

In this method, since a Si-containing thin film is formed by using an organic Si-containing compound free from Cl represented by the above formula (I), Cl is not incorporate in the film. Therefore, the resulting film has high strength. Also it is made possible to inhibit cracks caused by Cl generated in the case of forming a Si-containing thin film using a conventional chlorine-containing Si—Si compound.

Since the organic Si-containing compound utilized of the present invention is likely to form Si—N—H based active hydrogen type radical activated species, which serve as a nucleus for formation of a film, under film forming conditions at low temperature, vapor phase growth can be conducted at lower temperature as compared with the conventional organic Si-containing compound. Furthermore, since the organic Si-containing compound is excellent in vaporization stability, a Si-containing thin film can be formed at high film forming rate.

The method of forming a Si-containing thin film of the present invention may be a method wherein a film forming method is a chemical vapor deposition method or a liquid phase epitaxy method.

### DESCRIPTION OF PREFERRED EMBODIMENTS

The embodiments of the present invention will be described below with reference to the accompanying drawings.

The present invention relates to a method of forming an Si-containing thin film using an organic Si-containing compound which has a Si—Si bond. The organic Si-containing compound is suitable as a stock for Si-containing thin films such as Si₃N₄ thin film and Hf—O—Si thin film formed by a MOCVD method or a liquid phase epitaxy method.

The method of forming a Si-containing thin film of the present invention comprises forming a film using an organic Si-containing compound having a Si—Si bond represented by the following formula (I):

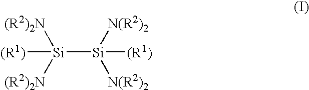

wherein R¹ represents a hydrogen or a methyl group, and R² represents a methyl group, an ethyl group, a propyl group or a tertiary butyl group.

Since a Si-containing thin film is formed by using an organic Si-containing compound free from Cl represented by the above formula (I), Cl is not comprised in the film. Therefore, the resulting film has high strength. Also, it is made possible to inhibit cracks caused by Cl evolved in the case of forming a Si-containing thin film using a conventional chlorine-containing Si—Si compound.

As shown in the following formula (II), heat Δ causes cleavage of a linkage at the position indicated by the dotted line and the organic Si-containing compound easily forms Si—N—H based active hydrogen type radical activated species, which serve as a nucleus for formation of a film, under film forming conditions at low temperature such as a temperature below 700° C., vapor phase growth can be conducted at lower temperature as compared with the conventional organic Si-containing compound. Furthermore, since the organic Si-containing compound is excellent in vaporization stability, a Si-containing thin film can be formed at high film forming rate.

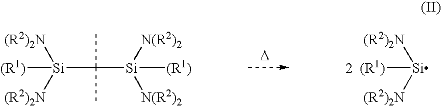

In the formula (I), R¹ is defined as a hydrogen or a methyl group, and R² is defined as a methyl group, an ethyl group, a propyl group or a tertiary butyl group. The reason of the definition is that an increase in the number of carbon atoms leads to poor thermal stability, and thus cleavage of a linkage is likely to occur from the terminal of the group.

The organic Si-containing compound of the present invention, for example, 1,1,2,2-tetrakis(diethylamino)dimethyldisilane, which is a compound of the above general formula (I) wherein R¹ is a methyl group and R² is an ethyl group, is produced in the following manner. Tetrahydrofuran (hereinafter referred to as THF) containing lithium dispersed therein was mixed with di(diethylamino)methylchlorosilane ((Et₂N)₂SiMeCl) and the mixed solution was reacted while stirring under the conditions of a temperature of 110 to 130° C. and a pressure of 1.0 mmHg for about 96 hours to obtain 1,1,2,2-tetrakis(diethylamino)dimethyldisilane which is liquid at normal temperature at a yield of about 76%.

The organic Si-containing compound thus obtained forms a Si-containing thin film on a substrate such as a silicon substrate, using a chemical vapor deposition method or a liquid phase epitaxy method. Since the organic Si-containing compound represented by formula (I) is liquid at the normal temperature, thermal CVD method is preferably employed.

The method of forming a Si-containing thin film using an organic Si-containing compound will now be described below, by taking a method of forming a Si₃N₄ thin film by the MOCVD method as an example.

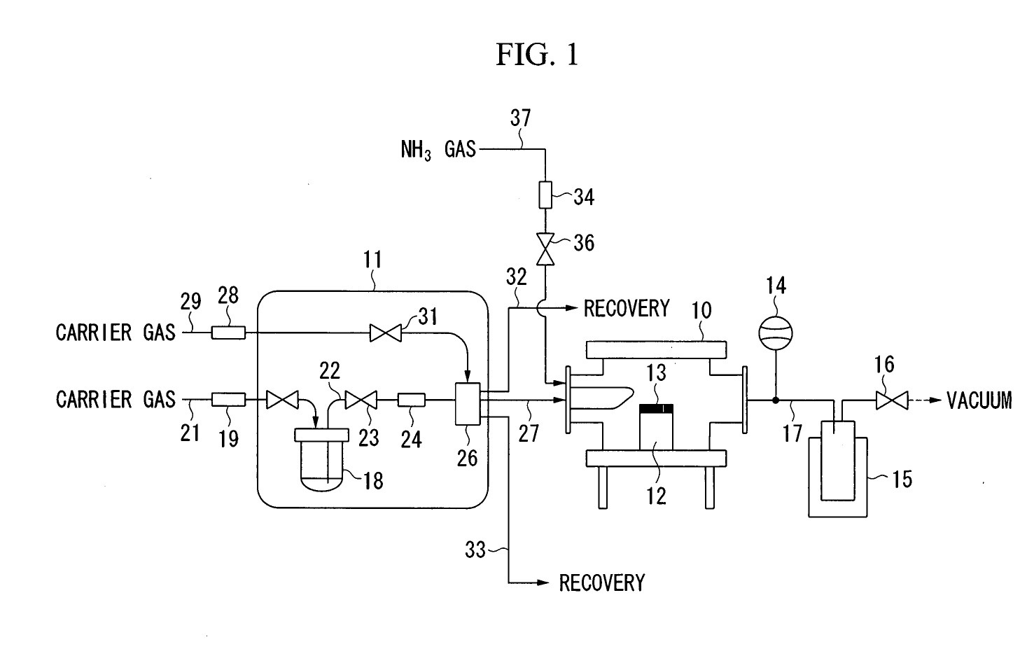

As shown in FIG. 1, an MOCVD apparatus comprises a film forming chamber 10 and a vapor generation device 11. The film forming chamber 10 is provided with a heater 12 installed therein, while a substrate 13 is placed on the heater 12. The inside of the film forming chamber 10 is evacuated through a pipe 17 that has a pressure sensor 14, a cold trap 15 and a needle valve 16. Connected via a needle valve 36 and a gas flow rate control device 34 to the film forming chamber 10 is an NH₃ gas feed pipe 37. In the case of a thin film containing oxygen, such as a SiO₂ thin film, is to be formed, O₂ gas is introduced through the gas feed pipe 37. The vapor generation device 11 is provided with a stock feed container 18 that stores the organic Si-containing compound represented by formula (I) of the present invention which is liquid at normal temperature. Connected to the stock feed container 18 via a gas flow rate control device 19 is a inert gas feed pipe 21 wherein the gas is utilized for pressurization. A material supply pipe 22 is also connected to the stock feed container 18. The material supply pipe 22 is provided with a needle valve 23 and a gas flow rate control device 24, and is connected to a vaporization chamber 26. Connected to the vaporization chamber 26 via a needle valve 31 and a gas flow rate control device 28 is a carrier gas feed pipe 29. The vaporization chamber 26 is also connected to the film forming chamber 10 by a pipe 27. A gas drain 32 and a drain 33 are also connected to the vaporization chamber 26.

In this apparatus, the pressurizing inert gas is introduced through the feed pipe 21 into the stock feed container 18, and the stock feed liquid stored in the stock feed container 18 is transferred by the material feed pipe 22 to the vaporization chamber 26. The organic Si-containing compound which has been vaporized in the vaporization chamber 26 is further supplied via the piping 27 to the film forming chamber 10 by the carrier gas that has been introduced through the carrier gas feed pipe 29 into the vaporization chamber 26. In the film forming chamber 10, vapor of the organic Si-containing compound is thermally decomposed and reacted with NH₃ gas introduced through the NH₃ gas feed pipe 37, and Si₃N₄ that is produced is deposited on the heated substrate 13 to form a Si₃N₄ thin film. Argon, helium, nitrogen or the like may be used as the pressurizing inert gas and the carrier gas.

When a film is formed by using the organic Si-containing compound having a Si—Si bond of the present invention, high vaporization stability and high film forming rate can be achieved. It is also made possible to carry out vapor deposition at a temperature lower than that of the organic Si-containing compound used in the prior art, and produce an Si-containing thin film having higher strength in which cracks are less likely to occur. The thickness of the Si-containing thin film of the present invention is preferably 50 nm or less.

A method of forming a Si—O—Hf thin film will now be described below by way of an example.

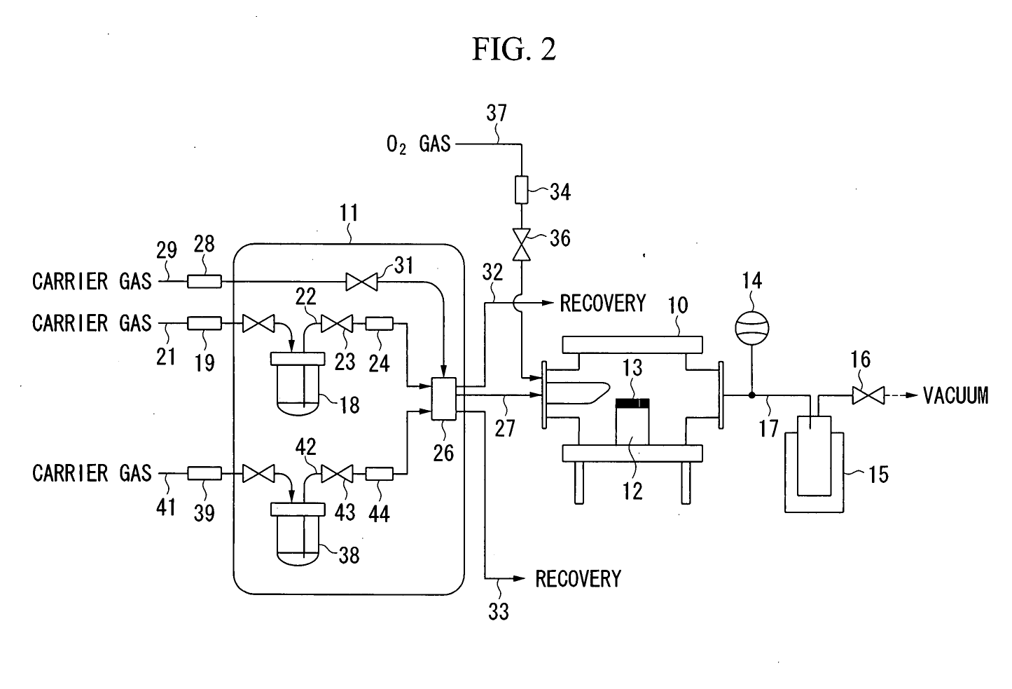

As shown in FIG. 2, a stock feed container 38 stores a stock feed liquid different from the organic Si-containing compound of the present invention, for example a stock solution containing an organic hafnium compound, is provided in the vapor generation device 11 of the MOCVD apparatus shown in FIG. 1. Connected via a gas flow rate control device 39 to the stock feed container 38 is a inert gas feed pipe 41 wherein the gas is utilized for pressurization. A material feed pipe 42 is also connected to the feed stock container 38. The material feed pipe 42 has a needle valve 43 and a gas flow rate control device 44, and is connected to the vaporization chamber 26. Thus, in an arrangement similar to the piping that is connected to the stock feed container 18 storing the organic Si-containing compound, an O₂ gas is introduced through the gas feed pipe 37.

In this apparatus, the organic Si-containing compound and the organic hafnium compound which have been transferred from the stock feed containers 18 and 38, respectively, and turned into vapor, are supplied to the film forming chamber 10. In the film forming chamber 10, vapors of the organic Si-containing compound and the organic hafnium compound are decomposed by thermal decomposition and caused to react with O₂ gas introduced through the O₂ gas feed pipe 37, and Si—O—Hf that has been generated is deposited on the heated substrate 13 to form a Si—O—Hf thin film.

### EXAMPLES

The Examples and Comparative Examples of the present invention will be described in detail below.

### Example 1

THF containing lithium dispersed therein was mixed with ((CH₃)₂N)₂SiHCl and the mixed solution was reacted while stirring under the conditions of a temperature of 110 to 130° C. and a pressure of 1.0 mmHg for 96 hours to obtain a substance which is liquid at normal temperature. Elemental analysis of the resulting liquid resulted in Si=23.93, C=41.02, H=11.11 and N=23.92. Also, mass spectrometric analysis resulted in m/e=117 and m/e=233. Furthermore, ¹H-NMR (C₆D₆) result in δ1.15 (CH₃), δ1.22 (CH₃), δ2.31 (C—H, d) and δ5.3 (H, q). The above analytical results identified that the resulting liquid has a structure represented by the above formula (I) and is 1,1,2,2-tetrakis(dimethylamino)disilane[H((CH₃)₂N)₂Si—Si(N(CH₃)₂)₂H] wherein R¹ is H and R² is CH₃.

### Example 2

In the same manner as in Example 1, except that ((C₂H₅)₂N)₂SiHCl was used in place of ((CH₃)₂N)₂SiHCl, the reaction was conducted to obtain 1,1,2,2-tetrakis(diethylamino)disilane[H((C₂H₆)₂N)₂Si—Si(N(C₂H₆)₂)₂H] having a structure represented by the above formula (I) wherein R¹ is H and R² is C₂H₆.

### Example 3

In the same manner as in Example 1, except that ((C₃H₇)₂N)₂SiHCl was used in place of ((CH₃)₂N)₂SiHCl, the reaction was conducted to obtain 1,1,2,2-tetrakis(dinormalpropylamino)disilane[H((C₃H₇)₂N)₂Si—Si(N(C₃H₇)₂)₂H] having a structure represented by the above formula (I) wherein R¹ is H and R² is C₃H₇.

### Example 4

In the same manner as in Example 1, except that ((CH(CH₃)₂)₂N)₂SiHCl was used in place of ((CH₃)₂N)₂SiHCl, the reaction was conducted to 1,1,2,2-tetrakis(diisopropylamino)disilane[H((CH(CH₃)₂)₂N)₂Si—Si(N(CH(CH₃)₂)₂)₂H] having a structure represented by the above formula (I) wherein R¹ is H and R² is CH(CH₃)₂.

### Example 5

In the same manner as in Example 1, except that ((C(CH₃)₃)₂N)₂SiHCl was used in place of ((CH₃)₂N)₂SiHCl, the reaction was conducted to obtain 1,1,2,2-tetrakis(ditertiarybutylamino)disilane[H((C(CH₃)₃)₂N)₂Si—Si(N(C(CH₃)₃)₂)₂H] having a structure represented by the above formula (I) wherein R¹ is H and R² is C(CH₃)₃.

### Example 6

In the same manner as it Example 1, except that ((CH₃)₂N)₂Si(CH₃)Cl was used in place of ((CH₃)₂N)₂SiHCl, the reaction was conducted to obtain 1,1,2,2-tetrakis(dimethylamino)dimethyldisilane[(CH₃) ((CH₃)₂N)₂Si—Si(N(CH₃)₂)₂(CH₃)] having a structure represented by the above formula (I) wherein R¹ is CH₃ and R² is CH₃.

### Example 7

In the same manner as in Example 1, except that ((C₂H₅)₂N)₂Si(CH₃)Cl was used in place of ((CH₃)₂N)₂SiHCl, the reaction was conducted to obtain 1,1,2,2-tetrakis(diethylamino)dimethyldisilane[(CH₃)((C₂H₅)₂N)₂Si—Si(N(C₂H₅)₂)₂(CH₃)] having a structure represented by the above formula (I) wherein R¹ is CH₃ and R² is C₂H₅.

### Example 8

In the same manner as in Example 1, except that ((C₃H₇)₂N)₂Si(CH₃)Cl was used in place of ((CH₃)₂N)₂SiHCl, the reaction was conducted to obtain 1,1,2,2-tetrakis(dinormalpropylamino)dimethyldisilane[(CH₃)((C₃H₇)₂N)₂Si—Si(N(C₃H₇)₂)₂(CH₃)] having a structure represented by the above formula (I) wherein R¹ is CH₃ and R² is C₃H₇.

### Example 9

In the same manner as in Example 1, except that ((CH(CH₃)₂)₂N)₂Si(CH₃)Cl was used in place of ((CH₃)₂N)₂SiHCl, the reaction was conducted to obtain 1,1,2,2-tetrakis(diisopropylamino)dimethyldisilane[(CH₃)((CH(CH₃)₂)₂N)₂Si—Si(N(CH(CH₃)₂)₂)₂(CH₃)] having a structure represented by the above formula (I) wherein R¹ is CH₃ and R² is CH(CH₃)₂.

### Example 10

In the same manner as in Example 1, except that ((C(CH₃)₃)₂N)₂Si(CH₃)Cl was used in place of ((CH₃)₂N)₂SiHCl, the reaction was conducted to obtain 1,1,2,2-tetrakis(ditertiarybutylamino)dimethyldisilane[(CH₃)((C(CH₃)₃)₂N)₂Si—Si(N(C(CH₃)₃)₂)₂(CH₃)] having a structure represented by the above formula (I) wherein R¹ is CH₃ and R² is C(CH₃)₃.

### Comparative Example 1

Cl₃Si—SiCl₃ was prepared and this compound was used as an organic Si-containing compound as it is.

### Comparative Example 2

In the same manner as in Example 1, except that (H₂N)₂SiHCl was used in place of ((CH₃)₂N)₂SiHCl, the reaction was conducted to obtain 1,1,2,2-tetrakisaminodisilane[H(H₂N)₂Si—Si(NH₂)₂H] having a structure represented by the above formula (I) wherein R¹ is H and R² is H.

### Comparative Example 3

In the same manner as in Example 1, except that ((C₄H₉)₂N)₂SiHCl was used in place of ((CH₃)₂N)₂SiHCl, the reaction was conducted to obtain 1,1,2,2-tetrakis(dinormalbutylamino)disilane[H((C₄H₉)₂N)₂Si—Si(N(C₄H₉)₂)₂H] having a structure represented by the above formula (I) wherein R¹ is H and R² is C₄H₉.

### Comparative Example 4

In the same manner as in Example 1, except that ((CH₂CH(CH₃)₂)₂N) ₂SiHCl was used in place of ((CH₃)₂N)₂SiHCl, the reaction was conducted to obtain 1,1,2,2-tetrakis(di-1-methylpropylamino)disilane[H((CH₂CH(CH₃)₂)₂N)₂Si—Si(N(CH₂CH(CH₃)₂)₂)₂H] having a structure represented by the above formula (I) wherein R¹ is H and R² is CH₂CH(CH₃)₂.

### Comparative Example 5

In the same manner as in Example 1, except that ((CH(CH₃)(C₂H₅))₂N)₂SiHCl was used in place of ((CH₃)₂N)₂SiHCl, the reaction was conducted to obtain 1,1,2,2-tetrakis(di-2-methylpropylamino)disilane[H((CH(CH₃)(C₂H₅))₂N)₂Si—Si(N(CH(CH₃)(C₂H₅))₂)₂H] having a structure represented by the above formula (I) wherein R¹ is H and R² is CH(CH₃)(C₂H₅).

### Comparative Example 6

In the same manner as in Example 1, except that ((C₅H₁₁)₂N)₂SiHCl was used in place of ((CH₃)₂N)₂SiHCl, the reaction was conducted to obtain 1,1,2,2-tetrakis(dinormalpentylamino)disilane[H((C₅H₁₁)₂N)₂Si—Si(N(C₅H₁₁)₂)₂H] having a structure represented by the above formula (I) wherein R¹ is H and R² is C₅H₁₁.

### Comparative Example 7

In the same manner as in Example 1, except that ((C₄H₉)₂N)₂Si(CH₃)Cl was used in place of ((CH₃)₂N)₂SiHCl, the reaction was conducted to obtain 1,1,2,2-tetrakis(dinormalbutylamino)dimethyldisilane[(CH₃)((C₄H₉)₂N)₂Si—Si(N(C₄H₉)₂)₂(CH₃)] having a structure represented by the above formula (I) wherein R¹ is CH₃ and R² is C₄H₉.

### Comparative Example 8

In the same manner as in Example 1, except that ((CH₂CH(CH₃)₂)₂N)₂Si(CH₃)Cl was used in place of ((CH₃)₂N)₂SiHCl, the reaction was conducted to obtain 1,1,2,2-tetrakis(di-1-methylpropylamino)dimethyldisilane[(CH₃)((CH₂CH(CH₃)₂)₂N)₂Si—Si(N(CH₂CH(CH₃)₂)₂)₂ (CH₃)] having a structure represented by the above formula (I) wherein R¹ is CH₃ and R² is CH₂CH(CH₃)₂.

### Comparative Example 9

In the same manner as in Example 1, except that ((CH(CH₃)(C₂H₅))₂N)₂Si(CH₃)Cl was used in place of ((CH₃)₂N)₂SiHCl, the reaction was conducted to obtain 1,1,2,2-tetrakis(di-2-methylpropylamino)dimethyldisilane[(CH₃)((CH(CH₃)(C₂H₅))₂N)₂Si—Si(N(CH(CH₃)(C₂H₅))₂)₂(CH₃)] having a structure represented by the above formula (I) wherein R¹ is CH₃ and R² is CH(CH₃)(C₂H₅).

### Comparative Example 10

In the same manner as in Example 1, except that ((C₅H₁₁)₂N)₂Si(CH₃)Cl was used in place of ((CH₃)₂N)₂SiHCl, the reaction was conducted to obtain 1,1,2,2-tetrakis(dinormalpentylamino)dimethyldisilane[(CH₃)((C₅H₁₁)₂N)₂Si—Si(N(C₅H₁₁)₂)₂(CH₃)] having a structure represented by the above formula (I) wherein R¹ is CH₃ and R² is C₅H₁₁.

### Comparative Example 11

In the same manner as in Example 1, except that ((CH₃)₂N)₂Si(C₂H₅)Cl was used in place of ((CH₃)₂N)₂SiHCl, the reaction was conducted to obtain 1,1,2,2-tetrakis(dinormalpentylamino)dimethyldisilane[(C₂H₅)((CH₃)₂N)₂Si—Si(N(CH₃)₂)₂(C₂H₅)] having a structure represented by the above formula (I) wherein R¹ is C₂H₅ and R² is CH₃.

### Comparative Evaluation 1

Using the organic Si-containing compounds obtained in Examples 1 to 10 and Comparative Examples 1 to 11, the following tests were conducted.

First, five silicon substrates were prepared and then disposed in a film forming chamber of a MOCVD apparatus shown in FIG. 1. Then, the substrate temperature was set to 500° C. and the vaporization temperature was set to 100° C., and the pressure was set to about 266 Pa (2 torr). Using a NH₃ gas as a reactant gas, its partial pressure was set to 100 ccm. Using an Ar gas as a carrier gas, each organic Si-containing compound was supplied at a rate of 0.05 cc/min and each substrate was taken out from the film forming chamber upon arrival of a film forming time of 1, 2, 3, 4 or 5 minutes. Then, the film thickness of a Si₃N₄ thin film on each substrate was measured by the SEM (scanning electron microscope) image of the cross section. The results of the film thickness per film forming time are shown in Table 1.

TABLE 1

| | Organic Si- | Structure of atomic | | Film thickness per film | | | | |
|---|---|---|---|---|---|---|---|---|
| | containing | group | | forming time (nm) | | | | |
| | compound | R¹ | R² | 1 min. | 2 min. | 3 min. | 4 min. | 5 min. |
| Example 1 | [(R¹) ((R²)₂N)₂Si]₂ | H | CH₃ | 0.1 | 0.23 | 0.33 | 0.4 | 0.54 |
| Example 2 | | H | C₂H₅ | 0.1 | 0.25 | 0.35 | 0.42 | 0.53 |
| Example 3 | | H | C₃H₇ | 0.1 | 0.23 | 0.36 | 0.45 | 0.52 |
| Example 4 | | H | CH(CH₃)₂ | 0.1 | 0.24 | 0.33 | 0.42 | 0.50 |
| Example 5 | | H | C(CH₃)₃ | 0.2 | 0.33 | 0.41 | 0.54 | 0.61 |
| Example 6 | | CH₃ | CH₃ | 0.1 | 0.21 | 0.34 | 0.43 | 0.52 |
| Example 7 | | CH₃ | C₂H₅ | 0.2 | 0.35 | 0.44 | 0.52 | 0.60 |
| Example 8 | | CH₃ | C₃H₇ | 0.1 | 0.2 | 0.3 | 0.4 | 0.5 |
| Example 9 | | CH₃ | CH(CH₃)₂ | 0.1 | 0.19 | 0.29 | 0.41 | 0.51 |
| Example 10 | | CH₃ | C(CH₃)₃ | 0.1 | 0.2 | 0.3 | 0.42 | 0.49 |
| Comparative Example 9 | | CH₃ | CH(CH₃) (C₂H₅) | | | | | |
| Comparative Example 1 | Si₂Cl₆ | — | — | 0.01 | 0.02 | 0.025 | 0.03 | 0.032 |

| | | | | | | |
|---|---|---|---|---|---|---|
| Comparative Example 2 | [(R¹) ((R²)₂N)₂Si]₂ | H | H | 0.01-0.015 | 0.016-0.023 | 0.025 |
| Comparative Example 3 | | H | C₄H₉ | | | 0.025 |
| Comparative Example 4 | | H | CH₂CH(CH₃)₂ | 0.010-0.013 | 0.018-0.02 | 0.021 |
| Comparative Example 5 | | H | CH(CH₃) (C₂H₅) | | | 0.022 |
| Comparative Example 6 | | H | C₅H₁₁ | 0.009-0.018 | 0.018-0.02 | 0.021 |
| Comparative Example 7 | | CH₃ | C₄H₉ | | | 0.020 |
| Comparative Example 8 | | CH₃ | CH₂CH(CH₃)₂ | 0.007-0.009 | 0.008-0.011 | 0.015 |
| Comparative Example 9 | | CH₃ | CH(CH₃) (C₂H₅) | | | 0.016 |
| Comparative Example 10 | | CH₃ | C₅H₁₁ | 0.009-0.013 | 0.01-0.02 | 0.024 |
| Comparative Example 11 | | C₂H₅ | CH₃ | | | 0.025 |

As is apparent from Table 1, the thin films obtained by using the organic Si-containing compounds of Comparative Examples 1 to 11 were inferior in film forming stability because the film thickness did not increase over time. In contrast, the thin films obtained by using the organic Si-containing compounds of Examples 1 to 10 were excellent in film forming stability because the film thickness per film forming time became uniform.

### Comparative Evaluation 2

In the same manner as in Comparative Evaluation 1, except that the substrate temperature was changed to 700° C. or more, 600° C., 500° C. and 400° C,. a Si₃N₄ thin film was formed on each silicon substrate utilized with the organic Si-containing compounds obtained in Examples 1 to 10 and Comparative Examples 1 to 11. SEM micrograph of the surface of each substrate on which the thin film was formed was taken and the proportion of cracks per fixed area was determined. The results of the proportion of area of cracks are shown in Table 2.

TABLE 2

| | Proportion of cracks [%] | | | | | Proportion of cracks [%] | | | |
|---|---|---|---|---|---|---|---|---|---|
| | >700° C. | 600° C. | 500° C. | 400° C. | | >700° C. | 600° C. | 500° C. | 400° C. |
| Example 1 | 0.01 | 0.02 | 0.02 | 0.02 | Comparative | 0.1 | 0.2 | 0.5 | 1.0 |
| | | | | | Example 1 | | | | |
| Example 2 | 0.01 | 0.015 | 0.02 | 0.02 | Comparative | 0.1 | 0.22 | 0.51 | 0.93 |
| | | | | | Example 2 | | | | |
| Example 3 | 0.012 | 0.02 | 0.021 | 0.019 | Comparative | 0.1 | 0.25 | 0.55 | 0.98 |
| | | | | | Example 3 | | | | |
| Example 4 | 0.01 | 0.02 | 0.022 | 0.02 | Comparative | 0.1 | 0.28 | 0.6 | 1.0 |
| | | | | | Example 4 | | | | |
| Example 5 | 0.013 | 0.015 | 0.019 | 0.018 | Comparative | 0.15 | 0.20 | 0.57 | 1.0 |
| | | | | | Example 5 | | | | |
| Example 6 | 0.015 | 0.018 | 0.02 | 0.02 | Comparative | 0.1 | 0.19 | 0.58 | 1.0 |
| | | | | | Example 6 | | | | |
| Example 7 | 0.012 | 0.015 | 0.018 | 0.019 | Comparative | 0.12 | 0.15 | 0.6 | 0.98 |
| | | | | | Example 7 | | | | |
| Example 8 | 0.011 | 0.015 | 0.02 | 0.02 | Comparative | 0.13 | 0.2 | 0.56 | 0.85 |
| | | | | | Example 8 | | | | |
| Example 9 | 0.012 | 0.02 | 0.018 | 0.02 | Comparative | 0.1 | 0.2 | 0.49 | 0.88 |
| | | | | | Example 9 | | | | |
| Example 10 | 0.01 | 0.021 | 0.022 | 0.02 | Comparative | 0.10 | 0.23 | 0.6 | 0.93 |
| | | | | | Example 10 | | | | |
| | | | | | Comparative | 0.11 | 0.22 | 0.7 | 0.99 |
| | | | | | Example 11 | | | | |

As is apparent from Table 2, the proportion of area of cracks on the surface of each of the thin films obtained in Comparative Examples 1 to 11 exhibited a high value within a range from 0.1% to 1.0%. The proportion of cracks exhibited a remarkably high value under film forming conditions at low temperature. In contrast, the proportion of cracks on the surface of each of the thin films obtained in Examples 1 to 10 exhibited a remarkably inhibited value within a range from about 0.01% to 0.022%.

### Comparative Evaluation 3

Using the organic Si-containing compounds obtained in Examples 1 to 10 and Comparative Examples 1 to 11, the following tests were conducted.

First, each organic Si-containing compound was dissolved in an organic solvent to prepare a stock solution containing the organic Si-containing compound (0.5 mol). As the organic solvent, n-octane was used. For each stock solution, four 4-inch silicon wafers having a 1000 Å thick silicone oxide film on the surface thereof were prepared. Then, the stock solution was applied on the surface of a wafer using a spin coating method. The coating amount of the solution was controlled so that the thin film formed after a heat treatment had a thickness of 50 nm.

Then, the wafer having a surface coated with the stock solution was heat-treated under a N₂ atmosphere to form a Si₃N₄ thin film on the silicon oxide film of the wafer. The heat-treating temperature was changed to 700° C. or higher, 600° C., 500° C. and 400° C. for each stock solution. An SEM micrograph of the surface of the wafer on which the Si₃N₄ thin film was formed was taken and the proportion of area of cracks per fixed area was determined. The results of the proportion of cracks formed on the Si₃N₄ thin film surface are shown in Table 3.

TABLE 3

| | Proportion of cracks [%] | | | | | Proportion of cracks [%] | | | |
|---|---|---|---|---|---|---|---|---|---|
| | >700° C. | 600° C. | 500° C. | 400° C. | | >700° C. | 600° C. | 500° C. | 400° C. |
| Example 1 | 0.02 | 0.01 | 0.01 | 0.01 | Comparative | 0.5 | 0.4 | 0.3 | 0.5 |
| | | | | | Example 1 | | | | |
| Example 2 | 0.01 | 0.01 | 0.01 | 0.02 | Comparative | 0.3 | 0.2 | 0.5 | 0.3 |
| | | | | | Example 2 | | | | |
| Example 3 | 0.01 | 0.02 | 0.02 | 0.01 | Comparative | 0.2 | 0.4 | 0.3 | 0.2 |
| | | | | | Example 3 | | | | |
| Example 4 | 0.02 | 0.01 | 0.03 | 0.02 | Comparative | 0.5 | 0.4 | 0.2 | 0.4 |
| | | | | | Example 4 | | | | |
| Example 5 | 0.01 | 0.03 | 0.02 | 0.04 | Comparative | 0.4 | 0.3 | 0.2 | 0.3 |
| | | | | | Example 5 | | | | |
| Example 6 | 0.01 | 0.03 | 0.01 | 0.02 | Comparative | 0.3 | 0.4 | 0.5 | 0.2 |
| | | | | | Example 6 | | | | |
| Example 7 | 0.01 | 0.02 | 0.01 | 0.02 | Comparative | 0.3 | 0.4 | 0.5 | 0.1 |
| | | | | | Example 7 | | | | |
| Example 8 | 0.01 | 0.03 | 0.02 | 0.01 | Comparative | 0.3 | 0.4 | 0.3 | 0.2 |
| | | | | | Example 8 | | | | |
| Example 9 | 0.01 | 0.02 | 0.01 | 0.01 | Comparative | 0.2 | 0.3 | 0.1 | 0.3 |
| | | | | | Example 9 | | | | |
| Example 10 | 0.01 | 0.02 | 0.03 | 0.01 | Comparative | 0.4 | 0.5 | 0.3 | 0.4 |
| | | | | | Example 10 | | | | |
| | | | | | Comparative | 0.5 | 0.3 | 0.2 | 0.4 |
| | | | | | Example 11 | | | | |

As is apparent from Table 3, the proportion of cracks on the surface of each of the thin films obtained in Comparative Examples 1 to 11 exhibited a high value within a range from 0.1% to 0.5%. In contrast, the proportion of cracks on the surface of each of the thin films obtained in Examples 1 to 10 exhibited a remarkably inhibited value within a range from about 0.01% to 0.04%.

As described above, the method of forming a Si-containing thin film of the present invention comprises forming a film using an organic Si-containing compound having a Si—Si bond represented by the above formula (I). Since the Si-containing thin film is formed by using an organic Si-containing compound free from Cl having such a structure, Cl is not incorporated-into the film. Therefore, the resulting film has high strength. Also, it is made possible to inhibit cracks caused by Cl evolved in the case of forming a Si-containing thin film using a conventional chlorine-containing Si—Si compound.

Since the organic Si-containing compound is likely to form Si—N—H based active hydrogen type radical activated species, which serve as a nucleus for formation of a film, under film forming conditions at low temperature, vapor phase growth can be conducted at a temperature lower than that of the conventional organic Si-containing compound. Furthermore, since the organic Si-containing compound is excellent in vaporization stability, a Si-containing thin film can be formed at high film forming rate.

What is claimed is:

1. A method of forming a Si-containing thin film, which comprises a step of forming a film using an organic Si-containing compound having a Si—Si bond represented by the following formula (I): 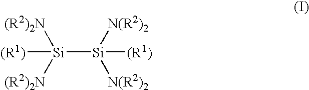
wherein R¹ represents a hydrogen or a methyl group, and R² represents a methyl group, an ethyl group, a propyl group or a tertiary butyl group.

2. The method of forming a Si-containing thin film according to claim 1, wherein the film forming method is one of a chemical vapor deposition method and a liquid phase epitaxy method.

3. The method of forming a Si-containing thin film according to claim 2, wherein the chemical vapor deposition method is a thermal chemical vapor deposition method.

4. The method of forming a Si-containing thin film according to claim 1, wherein the Si-containing thin film formed is at least one selected from a Si₃N₄ thin film, a SiO₂ thin film, and a Hf—O—Si thin film.

5. The method of forming a Si-containing thin film according to claim 2, comprising steps of vaporizing the organic Si-containing compound, thermally decomposing the vaporized organic Si-containing compound and allowing the decomposed organic Si-containing compound to react with one of NH₃ gas and O₂ gas.

6. The method of forming a Si-containing thin film according to claim 2, comprising steps of vaporizing the organic Si-containing compound and an organic hafnium compound, thermally decomposing the vaporized organic Si-containing compound and the vaporized organic hafnium compound, and allowing the decomposed compounds to react with O₂ gas.

7. The method of forming a Si-containing thin film according to claim 1, wherein the formed Si-containing thin film does not contain Cl.

8. The method of forming a Si-containing thin film according to claim 1, wherein forming the film is conducted at a temperature not greater than 700° C.

9. The method of forming a Si-containing thin film according to claim 1, wherein the film forming is performed in 5 minutes or less.

10. The method of forming a Si-containing thin film according to claim 1, wherein the thickness of the Si-containing thin film is 50 nm or less.
